(19) United States
(12) Patent Application Publication
(10) Pub. No.: US 2024/0324164 A1
(43) Pub. Date: Sep. 26, 2024

(54) INTEGRATED CIRCUIT

(71) Applicant: SAMSUNG ELECTRONICS CO., LTD., Suwon-si (KR)

(72) Inventors: Jeewoong Kim, Suwon-si (KR); Kyunghee Cho, Suwon-si (KR)

(21) Appl. No.: 18/608,017

(22) Filed: Mar. 18, 2024

(30) Foreign Application Priority Data
Mar. 24, 2023 (KR) 10-2023-0039311

(51) Int. Cl. H10B 10/00; H01L 23/528; H01L 27/092; H01L 29/06; H01L 29/423; H01L 29/775; H01L 29/786

(52) U.S. Cl. CPC H10B 10/125; H01L 23/5283; H01L 27/0922; H01L 29/0673; H01L 29/42392; H01L 29/775; H01L 29/78696

(57) ABSTRACT

According to the inventive concept, based on the layout of a 3-dimensional stack structure enabling minimization of the planar area occupied by unit cells and simplification of the configuration of a wiring connection structure between transistors defining at least a portion of an SRAM device, an integrated circuit with a reduced size and improved reliability may be implemented.

### CROSS-REFERENCE TO RELATED APPLICATIONS

This application is based on and claims priority under 35 U.S.C. § 119 to Korean Patent Application No. 10-2023-0039311, filed on Mar. 24, 2023, in the Korean Intellectual Property Office, the disclosure of which is incorporated by reference herein in its entirety.

### BACKGROUND

The present disclosure relates to an integrated circuit, and more particularly, to an integrated circuit including a field-effect transistor.

As the size of integrated circuits decreases, the degree of integration of field effect transistors on a substrate increases. Nano-sheet field effect transistors (NSFETs) including multiple nano-sheets stacked on the same layout region have been developed to increase the degree of integration. However, as the degree of integration of integrated circuits continues to increase and the size of integrated circuits continues to decrease, problems related to performance and reliability have arisen.

### SUMMARY

The inventive concept provides an integrated circuit having a 3-dimensional stack structure occupying a minimized planar area and having a simple wiring connection structure, and a layout thereof. By creating a 3-dimensional stack structure, a high degree of integration can be achieved while still minimizing the planar area occupied by unit cells.

Reducing the complexity of the wiring connection structure can be advantageous, as doing so reduces the process complexity, which can lower the likelihood of errors and reduce power consumption. Arranging a first set of gate patterns and a second set of gate patterns between power rails, with the first set of gate patterns defining a positive supply voltage terminal and the second set of gate patterns defining a negative supply voltage terminal at different vertical levels, e.g., heights, can simplify the wiring connection structure.

In addition, the technical goals to be achieved by the inventive concept are not limited to the technical goals mentioned above, and other technical goals may be clearly understood by one of ordinary skill in the art from the following descriptions.

In general, innovative aspects of the subject matter described in this specification can be embodied in an integrated circuit including a fin-type active pattern extending from a substrate in a first direction and protruding in a vertical direction, a plurality of first gate patterns at a first vertical level above the substrate, the plurality of first gate patterns being spaced apart from one another in the first direction, and crossing the fin-type active pattern in a second direction perpendicular to the first direction, a plurality of second gate patterns at a second vertical level higher than the first vertical level, the plurality of second gate patterns being spaced apart from one another in the first direction, and crossing the fin-type active pattern in the second direction, a first gate cut line and a second gate cut line cutting both of the plurality of first gate patterns and the plurality of second gate patterns with the fin-type active pattern therebetween, and extending in the first direction, a first power rail disposed inside the first gate cut line and extending in the first direction, and a second power rail disposed inside the second gate cut line and extending in the first direction, wherein, from among the plurality of first gate patterns, a first gate pattern applying a positive supply voltage penetrates through the second gate cut line and contacts a sidewall of the second power rail, and, from among the plurality of second gate patterns, a second gate pattern applying a negative supply voltage penetrates through the first gate cut line and contacts a sidewall of the first power rail.

Another general aspect can be embodied in an integrated circuit that includes a first fin-type active pattern and a second fin-type active pattern extending from a substrate in a first direction, spaced apart from each other in a second direction perpendicular to the first direction, and protruding in a vertical direction, a plurality of first gate patterns at a first vertical level above the substrate, the plurality of first gate patterns being spaced apart from one another in the first direction, and crossing first fin-type active pattern and the second fin-type active pattern in the second direction, a plurality of second gate patterns at a second vertical level higher than the first vertical level, the plurality of second gate patterns being spaced apart from one another in the first direction, and crossing the first fin-type active pattern and the second fin-type active pattern in the second direction, two first gate cut lines cutting both of the plurality of first gate patterns and the plurality of second gate patterns with the first fin-type active pattern and the second fin-type active pattern therebetween, and extending in the first direction, one second gate cut line disposed between the first fin-type active pattern and the second fin-type active pattern, cutting both of the plurality of first gate patterns and the plurality of second gate patterns, and extending in the first direction, first power rails arranged inside the first gate cut lines and extending in the first direction, and a second power rail disposed inside the second gate cut line and extending in the first direction, wherein, from among the plurality of first gate patterns, first gate patterns applying a positive supply voltage penetrate through the second gate cut line and contact sidewalls of the second power rail, and, from among the plurality of second gate patterns, second gate patterns applying a negative supply voltage penetrate through the first gate cut lines and contact sidewalls of the first power rails.

Another general aspect can be embodied in an integrated circuit including, to implement an SRAM device including six transistors in a 3-dimensional stack structure a fin-type active pattern extending from a substrate in a first direction and protruding in a vertical direction, a plurality of first gate patterns at a first vertical level above the substrate, the plurality of first gate patterns being spaced apart from one another in the first direction, and crossing the fin-type active pattern in a second direction perpendicular to the first direction, a plurality of second gate patterns at a second vertical level higher than the first vertical level, the plurality of second gate patterns being spaced apart from one another in the first direction, and crossing the fin-type active pattern in the a second direction, a first gate cut line and a second gate cut line cutting both of the plurality of first gate patterns and the plurality of second gate patterns with the fin-type active pattern therebetween, and extending in the first direction, a first power rail disposed inside the first gate cut line and extending in the first direction, and a second power rail disposed inside the second gate cut line and extending in the first direction, wherein, from among the plurality of first gate patterns, a first gate pattern applying a positive supply voltage is disposed to penetrate through the second gate cut line and contact a sidewall of the second power rail, from among the plurality of second gate patterns, a second gate pattern applying a negative supply voltage is disposed to penetrate through the first gate cut line and contact a sidewall of the first power rail, first gate patterns delincating a first pull-up transistor and a second pull-up transistor from among the plurality of first gate patterns are located with the first gate pattern applying the positive supply voltage therebetween, second gate patterns delincating a first pull-down transistor and a second pull-down transistor from among the plurality of second gate patterns are located with the second gate pattern applying the negative supply voltage therebetween, and second gate patterns delineating a first pass gate transistor and a second pass gate transistor from among the plurality of second gate patterns are located with the second gate patterns delineating the first pull-down transistor and the second pull-down transistor therebetween.

### BRIEF DESCRIPTION OF THE DRAWINGS

FIG. 1 depicts an example of a circuit diagram showing an integrated circuit.

FIG. 2 depicts an example of a conceptual diagram showing a stacked structure of an integrated circuit.

FIG. 3 depicts an example of a planar layout of a unit cell of an integrated circuit.

FIG. 4 depicts an example of a planar layout showing an integrated circuit. FIG. 5A is a cross-sectional view taken along a line A-A′ of FIG. 4; FIG. 5B is a cross-sectional view taken along a line B-B′ of FIG. 4; FIG. 5C is a cross-sectional view taken along a line C-C′ of FIG. 4;

FIG. 5D is a cross-sectional view taken along a line D-D′ of FIG. 4; FIG. 5E is a cross-sectional view taken along a line E-E′ of FIG. 4; FIG. 5F is a cross-sectional view taken along a line F-F′ of FIG. 4;

FIG. 6 depicts an example of a planar layout showing an integrated circuit. FIG. 7 depicts a cross-sectional view taken along a line G-G′ of FIG. 6.

FIG. 8 depicts an example of a planar layout showing an integrated circuit. FIG. 9 depicts a cross-sectional view taken along a line H-H′ of FIG. 8.

FIG. 10 depicts an example of a planar layout showing an integrated circuit.

FIGS. 11 to 22 depict cross-sectional views showing depicts an example of a method of manufacturing an integrated circuit.

FIG. 23 depicts a conceptual diagram showing depicts an example of the arrangement of transistors in an integrated circuit.

FIG. 24 depicts an example of a configuration diagram showing a system including an integrated circuit.

### DETAILED DESCRIPTION OF THE EMBODIMENTS

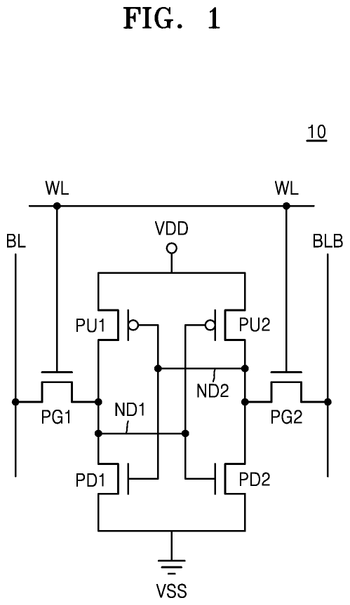

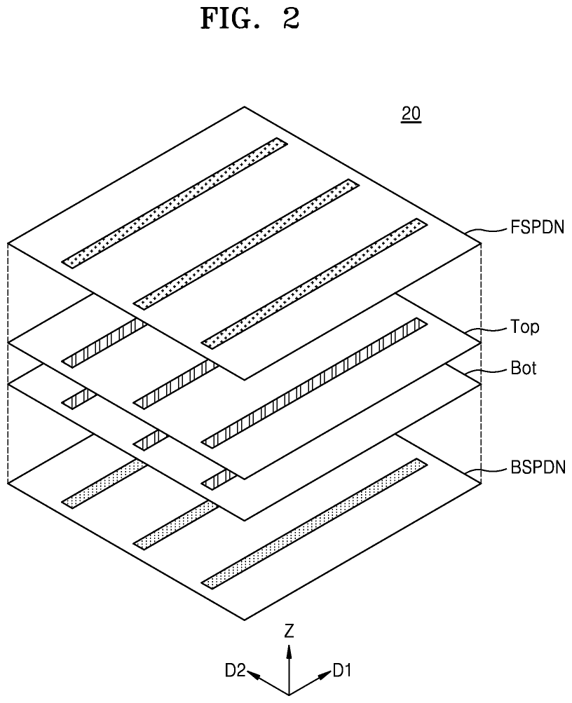

FIG. 1 depicts an example of a circuit diagram showing an integrated circuit 10. Referring to FIG. 1, the integrated circuit 10 including a 3-dimensional stacked field-effect transistor (FET) may be a static random access memory (SRAM) device including 6 transistors, as shown in the circuit diagram of FIG. 1. The integrated circuit 10 may include, for example, a first pass gate transistor PG1, a second pass gate transistor PG2, a first pull-up transistor PU1, a second pull-up transistor PU2, a first pull-down transistor PD1, and a second pull-down transistor PD2.

In some implementations, gates of the second pull-up transistor PU2 and the second pull-down transistor PD2 and a bit line BL are connected to a source/drain region of the first pass gate transistor PG1. Also, gates of the first pull-up transistor PU1 and the first pull-down transistor PD1 and a bit line bar BLB may be connected to a source/drain region of the second pass gate transistor PG2. In the implementations illustrated in FIG. 1 and other implementations described in this disclosure, the phrase source/drain region may be understood to mean a source terminal region or a drain terminal region of a transistor.

In some implementations, the first pass gate transistor PG1, the second pass gate transistor PG2, the first pull-down transistor PD1, and the second pull-down transistor PD2 are formed of nMOS-FETs, and the first pull-up transistor PU1 and the second pull-up transistor PU2 may be formed of pMOS-FETs. Also, the first pull-up transistor PU1 and the first pull-down transistor PD1 may delineate a complementary FET (cFET), and the second pull-up transistor PU2 and the second pull-down transistor PD2 may delineate a cFET. Also, the first pull-up transistor PU1 and the first pull-down transistor PD1, and the second pull-up transistor PU2 and the second pull-down transistor PD2, may delineate storage elements of the integrated circuit 10.

In the integrated circuit 10, the first pull-up transistor PU1 and the first pull-down transistor PD1, and the second pull-up transistor PU2 and the second pull-down transistor PD2, may be formed as FETs having a 3-dimensional stack (3DS) structure. Also, a FET having the 3DS structure may include a stacked nano-sheet structure. Hereinafter, a FET having the 3DS structure will be described in detail.

FIG. 2 depicts an example of a conceptual diagram showing a stacked structure of an integrated circuit 20. Referring to FIG. 2, the integrated circuit 20 may sequentially include a back-side power delivery network BSPDN, a bottom transistor layer Bot, a top transistor layer Top, and a front-side power delivery network FSPDN.

The bottom transistor layer Bot and the top transistor layer Top may be formed on a semiconductor substrate 101 (refer to FIG. 11). The front-side power delivery network FSPDN may be positioned above the top transistor layer Top, and the back-side power delivery network BSPDN may be positioned below the bottom transistor layer Bot. As shown in FIG. 2, signal patterns may be formed in the front-side power delivery network FSPDN, and power patterns may be formed in the back-side power delivery network BSPDN.

To supply power to transistors from the power patterns formed in the back-side power delivery network BSPDN, the integrated circuit 20 may include a power rail. Also, due to the existence of the back-side power delivery network BSPDN, some of the power patterns in the front-side power delivery network FSPDN may be omitted. Signal patterns may be arranged in a region of the front-side power delivery network FSPDN where some of the power patterns are omitted. Therefore, the integrated circuit 20 may provide relatively high routability.

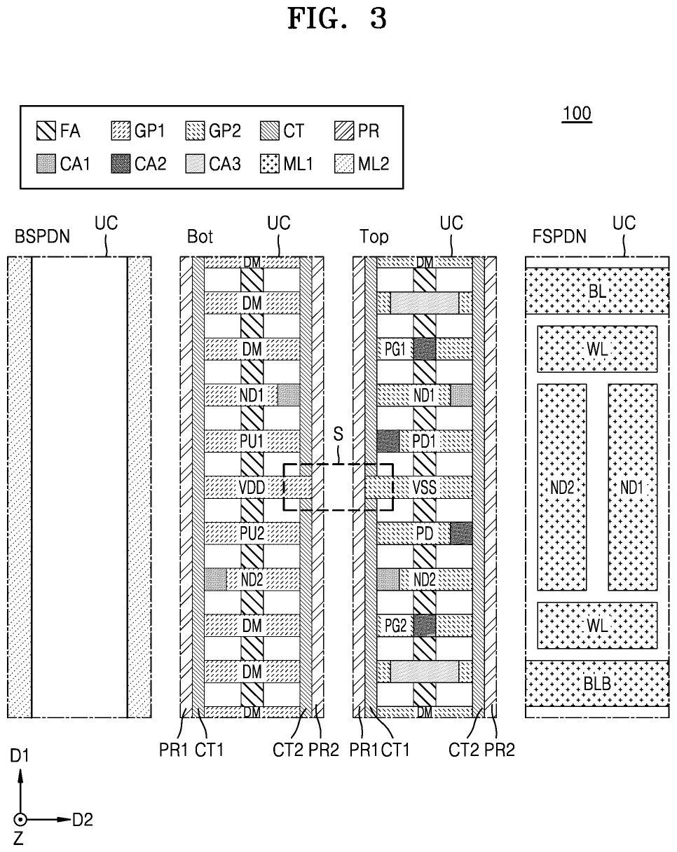

Hereinafter, a planar layout and a 3-dimensional structure of the integrated circuit 20 will be described in detail with reference to FIGS. 3 to 5F.

FIG. 3 depicts an example of a planar layout of a unit cell of an integrated circuit 100. FIG. 3 shows a planar layout of a stacked structure regarding a unit cell UC corresponding to 1-bit in the integrated circuit 100, where a rectangular portion indicated by dashed-dotted lines may correspond to 1-bit unit cell UC.

Here, although the back-side power delivery network BSPDN, the bottom transistor layer Bot, the top transistor layer Top, and the front-side power delivery network FSPDN are stacked in a vertical direction Z as described above with reference to FIG. 2, they are shown on one plane for convenience of explanation.

The unit cell UC may include a fin-type active pattern FA extending in a first direction D1 and protruding in the vertical direction Z, a plurality of first gate patterns GP1 spaced apart from one another in the first direction D1 and crossing the fin-type active pattern FA in a second direction D2 in the bottom transistor layer Bot, and a plurality of second gate patterns GP2 spaced apart from one another in the first direction D1 and crossing the fin-type active pattern FA in the second direction D2 in the top transistor layer Top. In other words, the first gate patterns GP1 and the second gate patterns GP2 cross the fin-type active pattern FA when view along a plan view along the vertical direction Z.

Also, in the integrated circuit 100 according to the inventive concept, the unit cell UC may include a gate cut line CT cutting both the plurality of first gate patterns GP1 and the plurality of second gate patterns GP2 with the fin-type active pattern FA therebetween and a power rail PR disposed outside the gate cut line CT and extending in the first direction D1. As used herein, the term “cutting” used in the figurative sense meaning to divide two sections.

In this example, the semiconductor substrate 101 (refer to FIG. 11) is a silicon (Si) wafer, and may include, for example, monocrystalline Si, polycrystalline Si, or amorphous Si. However, the material delincating the semiconductor substrate 101 is not limited to Si. In some implementations, the semiconductor substrate 101 may include a group IV semiconductor like germanium (Ge), a group IV-IV compound semiconductor like silicon germanium (SiGe) or silicon carbide (SiC), or a group III-V compound semiconductor like gallium arsenide (GaAs), indium arsenide (InAs), and indium phosphide (InP).

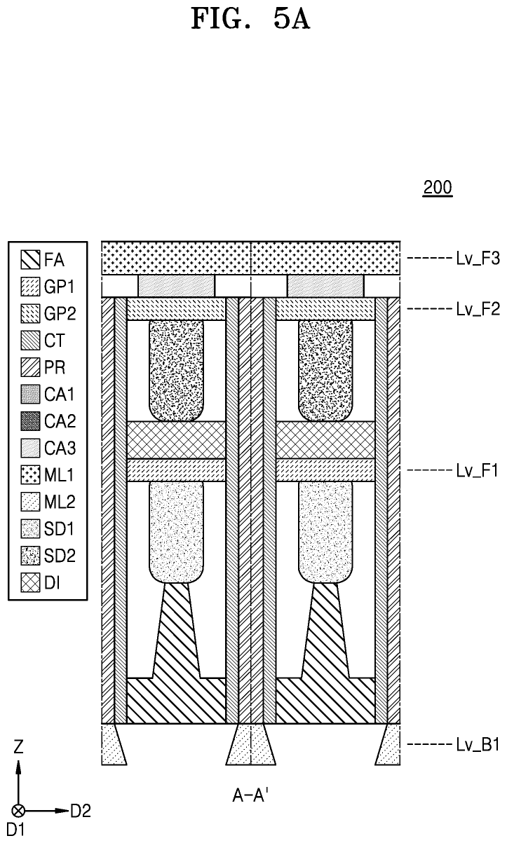

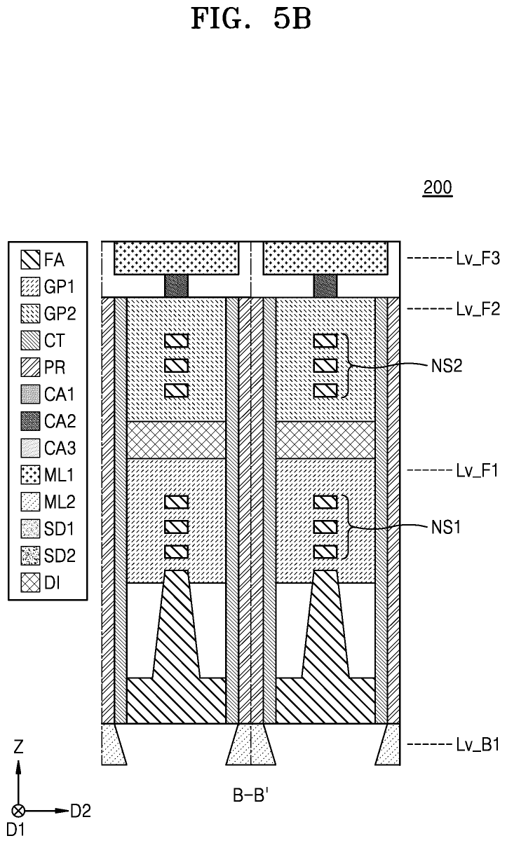

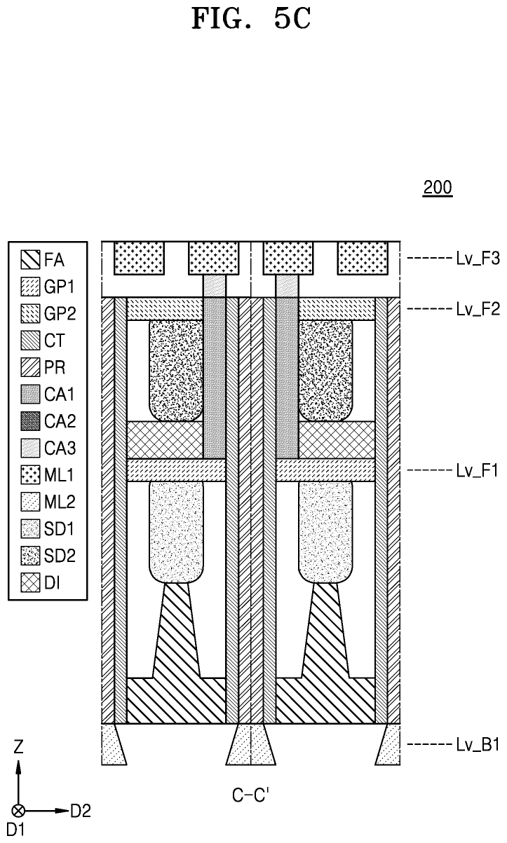

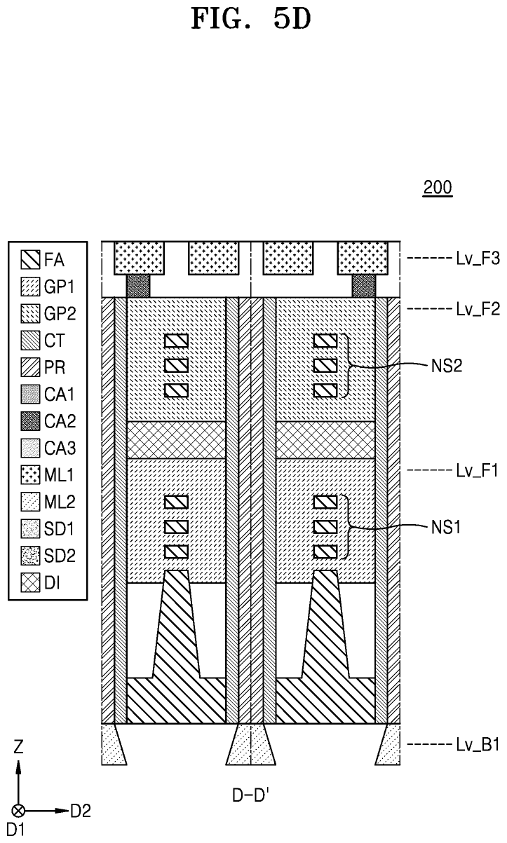

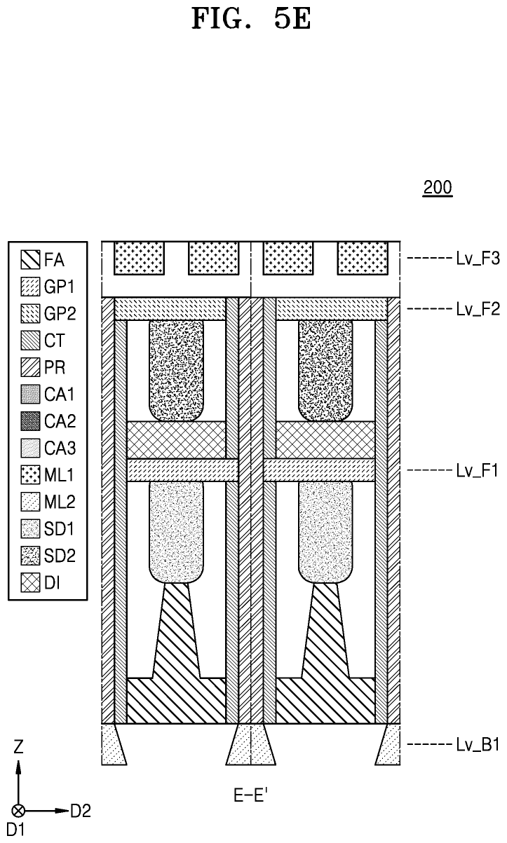

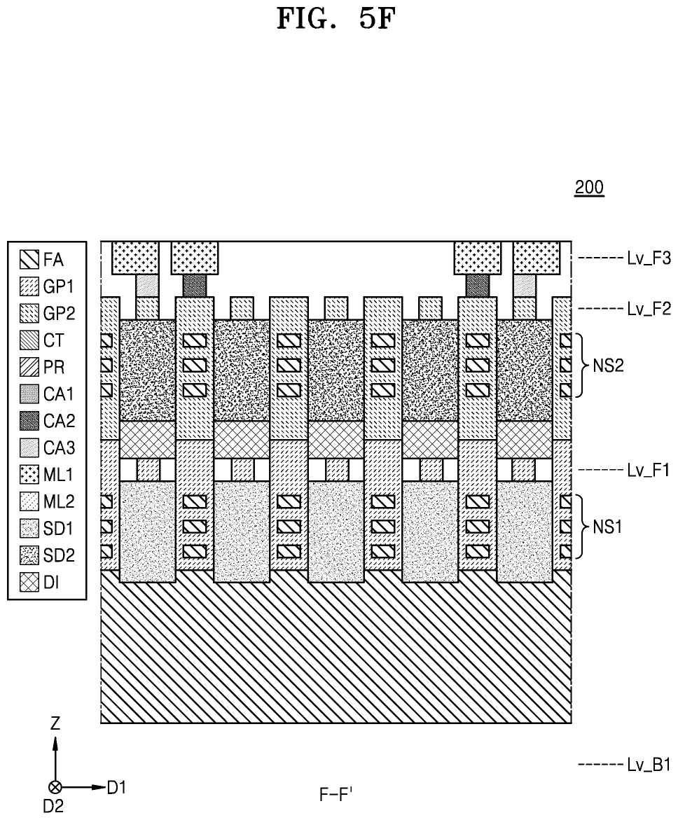

A shallow trench isolation (STI) defining a fin of the fin-type active pattern FA and a device isolation layer defining a device region may be formed in the semiconductor substrate 101. The device isolation layer may be formed to be deeper than the STI. Here, the fin-type active pattern FA extends in the first direction D1 on the semiconductor substrate 101 and includes a first nano-sheet NS1 (refer to FIG. 5B) disposed on the bottom transistor layer Bot and a second nano-sheet NS2 (refer to FIG. 5B) disposed on the top transistor layer Top. The first nano-sheet NS1 and the second nano-sheet NS2 may accurately overlap each other in the vertical direction Z.

A separating insulation layer (not shown) may be disposed between the first nano-sheet NS1 and the second nano-sheet NS2 to electrically insulate them from each other. In some implementations, source/drain regions (not shown) of a transistor may be formed on both side surfaces of the first nano-sheet NS1 and the second nano-sheet NS2 as regions more densely doped than a fin-type portion at the bottom of the fin-type active pattern FA.

The gate cut line CT extends in the first direction D1 while cutting both the plurality of first gate patterns GP1 and the plurality of second gate patterns GP2 with the fin-type active pattern FA therebetween. Therefore, the plurality of first gate patterns GP1 and the plurality of second gate patterns GP2 may have substantially the same width in the second direction D2.

For convenience of explanation, the gate cut line CT disposed to the left of the unit cell UC in the drawings from among gate cut lines CT is referred to as a first gate cut line CT1, whereas the gate cut line CT disposed to the right of the unit cell UC in the drawings from among the gate cut lines CT is referred to as a second gate cut line CT2. Also, the power rail PR disposed outside the first gate cut line CT1 and extending in the first direction D1 is referred to as a first power rail PR1, and the power rail PR disposed outside the second gate cut line CT2 and extending in the first direction D1 is referred to as a second power rail PR2. In some implementations, the first power rail PR1 and the second power rail PR2 extend in the vertical direction Z from the bottom transistor layer Bot to the top transistor layer Top.

First, the role of each of the plurality of first gate patterns GP1 positioned on the bottom transistor layer Bot will be described in detail. From among the plurality of first gate patterns GP1, a first gate pattern GP1 defining a positive supply voltage terminal VDD may penetrate through the second gate cut line CT2 in the second direction D2 to contact and be electrically connected to a sidewall of the second power rail PR2. The first gate pattern GP1 defining the positive supply voltage terminal VDD is located between the first gate patterns GP1 delincating the first pull-up transistor PU1 and the second pull-up transistor PU2. The first gate patterns GP1 delineating the first pull-up transistor PU1 and the second pull-up transistor PU2 are located between the first gate patterns GP1 delincating a first node ND1 and a second node ND2. The remaining first gate patterns GP1 from among the plurality of first gate patterns GP1 may be dummy patterns DM.

Next, the role of each of the plurality of second gate patterns GP2 positioned on the top transistor layer Top will be described in detail. From among the plurality of second gate patterns GP2, a second gate pattern GP2 defining a negative supply voltage terminal VSS may penetrate through the first gate cut line CT1 in the second direction D2 to contact and electrically connect to a sidewall of the first power rail PR1. The second gate pattern GP2 defining the negative supply voltage terminal VSS is located between the second gate patterns GP2 delincating the first pull-down transistor PD1 and the second pull-down transistor PD2. The second gate patterns GP2 delineating the first pull-down transistor PD1 and the second pull-down transistor PD2 are located between the second gate patterns GP2 delineating the first node ND1 and the second node ND2. The second gate patterns GP2 delineating the first node ND1 and the second node ND2 are located between the second gate patterns GP2 delincating the first pass gate transistor PG1 and the second pass gate transistor PG2. Also, the second gate patterns GP2 delineating the first pass gate transistor PG1 and the second pass gate transistor PG2 are located between the second gate patterns GP2 electrically connected to the bit line BL and the bit line bar BLB. Also, the remaining second gate patterns GP2 from among the plurality of second gate patterns GP2 may be the dummy patterns DM.

Referring to a portion S in FIG. 3, the positive supply voltage terminal VDD is connected to the second power rail PR2 at the bottom transistor layer Bot, and the negative supply voltage terminal VSS is connected to the first power rail PR1 at the top transistor layer Top. Here, the first gate pattern GP1 positioned on the bottom transistor layer Bot and defining the positive supply voltage terminal VDD and a second gate pattern GP2 positioned on the top transistor layer Top and defining the negative supply voltage terminal VSS may be arranged to overlap each other in the vertical direction Z.

Also, the first gate patterns GP1 located on the bottom transistor layer Bot and delineating the first pull-up transistor PU1 and the second pull-up transistor PU2 and the second gate patterns GP2 located on the top transistor layer Top and delincating the first pull-down transistor PD1 and the second pull-down transistor PD2 may be arranged to exactly overlap each other in the vertical direction Z.

Also, the first gate patterns GP1 located on the bottom transistor layer Bot and delineating the first node ND1 and the second node ND2 and the second gate patterns GP2 located on the top transistor layer Top and delineating the first node ND1 and the second node ND2 may be arranged to exactly overlap each other in the vertical direction Z.

A plurality of first wiring lines ML1 may be included in the front-side power delivery network FSPDN. From among the plurality of first wiring lines ML1, a first wiring line ML1 electrically connected to the first node ND1 may be disposed to face a first wiring line ML1 electrically connected to the second node ND2. From among the plurality of first wiring lines ML1, a first wiring line ML1 electrically connected to the second gate patterns GP2 delincating the first pass gate transistor PG1 and the second pass gate transistor PG2 may delineate a word line WL. Some of the plurality of first wiring lines ML1 may delineate the bit line BL and the bit line bar BLB.

A plurality of second wiring lines ML2 may be included in the back-side power delivery network BSPDN. The plurality of second wiring lines ML2 may delineate power patterns that supply power to the power rail PR. In some implementations, from among the plurality of second wiring lines ML2, a second wiring line ML2 electrically connected to the first power rail PR1 and a second wiring line ML2 electrically connected to the second power rail PR2 may be arranged to face each other.

The integrated circuit 100 according to the inventive concept includes a fin-type active pattern in which 1-bit unit cells UC are arranged in the layout structure described above, 6 transistors PU1, PU2, PD1, PD2, PG1, and PG2, and 2 nodes ND1 and ND2 and is based on a FET having a 3-dimensional stacked structure, thereby minimizing the planar area occupied by the unit cells UC.

A wiring connection structure between elements delineating transistors and a front-side power delivery network FSPDN may be configured simply. In other words, by arranging the plurality of first gate patterns GP1 and the plurality of second gate patterns GP2 between power rails PR extending in the first direction D1 and arranging the first gate pattern GP1 defining the positive supply voltage terminal VDD and the second gate pattern GP2 defining the negative supply voltage terminal VSS at different vertical levels, problems including the process complexity increasing according to the complexity of a wiring connection structure and a short-circuit between wires adjacent to each other may be resolved.

Ultimately, according to the inventive concept, based on the layout of a 3DS structure enabling minimization of the planar area occupied by the unit cells UC and simplification of the configuration of a wiring connection structure between transistors delineating an SRAM device, the integrated circuit 100 with a reduced size and improved reliability may be implemented.

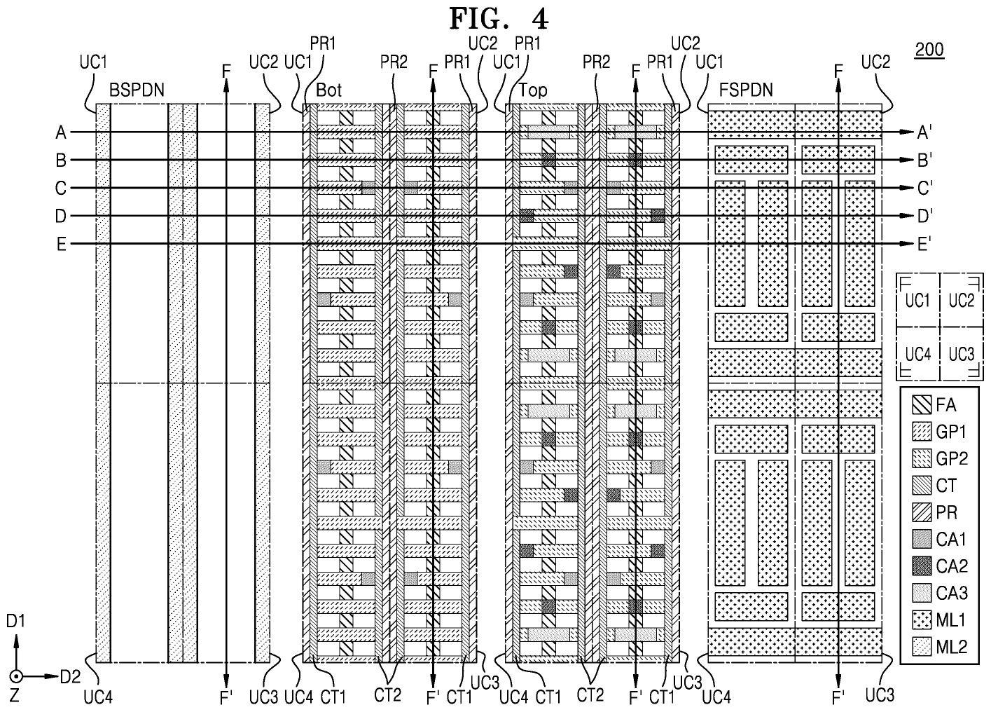

FIG. 4 depicts an example of a planar layout showing an integrated circuit 200, FIG. 5A is a cross-sectional view taken along a line A-A′ of FIG. 4, FIG. 5B is a cross-sectional view taken along a line B-B′ of FIG. 4, FIG. 5C is a cross-sectional view taken along a line C-C ‘of FIG. 4, FIG. 5D is a cross-sectional view taken along a line D-D’ of FIG. 4, FIG. 5E is a cross-sectional view taken along a line E-E′ of FIG. 4, and FIG. 5F is a cross-sectional view taken along a line F-F′ of FIG. 4.

Here, although the back-side power delivery network BSPDN, the bottom transistor layer Bot, the top transistor layer Top, and the front-side power delivery network FSPDN are stacked in a vertical direction Z as described above with reference to FIG. 2, they are shown on one plane for convenience of explanation.

Referring to FIGS. 4 and 5A to 5F together, in the integrated circuit 200, a planar layout of a stacked structure including 4 unit cells UC (refer to FIG. 3) corresponding to 1-bit in a 2×2 arrangement is shown, wherein a rectangular portion indicated by dashed-dotted lines may correspond to a 1-bit unit cell UC.

In the integrated circuit 200, first to fourth unit cells UC1, UC2, UC3, and UC4 may each have a structure in which the first nano-sheet NS1 and the second nano-sheet NS2 are horizontally surrounded by the first gate pattern GP1 and the second gate pattern GP2.

In some implementations, the integrated circuit 200 may have a gate all around (GAA) structure in which top surfaces and bottom surfaces of the first nano-sheet NS1 and the second nano-sheet NS2 and side surfaces thereof in the second direction D2 are surrounded by the first gate pattern GP1 and the second gate pattern GP2. Therefore, in a channel region including the first nano-sheet NS1 and the second nano-sheet NS2, a perimeter corresponding to the lengths of four sides of the channel region may correspond to a channel width. Meanwhile, when the thicknesses of the first nano-sheet NS1 and the second nano-sheet NS2 are maintained at several nanometers (nm), a quantum confinement effect may occur. By using the quantum confinement effect, a threshold voltage Vt of a transistor may be adjusted.

The first gate pattern GP1 and the second gate pattern GP2 may serve as gates of transistors and may each be disposed across the fin-type active pattern FA on the semiconductor substrate 101 (refer to FIG. 11) in the second direction D2. In detail, the first gate pattern GP1 may cover the first nano-sheet NS1, and the second gate pattern GP2 may cover the second nano-sheet NS2. Meanwhile, a gate dielectric layer (not shown) may be disposed between the first gate pattern GP1 and the first nano-sheet NS1 and between the second gate pattern GP2 and the second nano-sheet NS2. The gate dielectric layer may be formed as a high-k layer. The high-k layer may include a material having a higher dielectric constant than that of a silicon oxide. For example, the high-k layer may have a dielectric constant from about 10 to about 25.

In some implementations, the first gate pattern GP1 and the second gate pattern GP2 may each have a structure in which a metal nitride layer, a metal layer, a conductive capping layer, and a gap-filling metal-containing layer are sequentially stacked. For example, the first gate pattern GP1 and the second gate pattern GP2 may each have a stacked structure of TiAlC/TiN/W, a stacked structure of TiN/TaN/TiAlC/TiN/W, or a stacked structure of TiN/TaN/TiN/TiAlC/TiN/W.

The fin-type active pattern FA may include a first source/drain region SD1 and a second source/drain region SD2 on both side surfaces of the first gate pattern GP1 and the second gate pattern GP2 in the first direction D1. The first source/drain region SD1 and the second source/drain region SD2 may be connected to the first nano-sheet NS1 and the second nano-sheet NS2 nearby. The first source/drain region SD1 and the second source/drain region SD2 may include semiconductor layers epitaxially grown from the first nano-sheet NS1 and the second nano-sheet NS2. For example, the first source/drain region SD1 and the second source/drain region SD2 may include an epitaxially grown Si layer, an epitaxially grown SiC layer, an epitaxially grown SiGe layer, and the like. In some implementations, the first source/drain region SD1 and the second source/drain region SD2 may include different types of semiconductor layers.

Although not shown, gate spacers covering both sidewalls of the first gate pattern GP1 and the second gate pattern GP2 in the first direction D1 may be arranged. A gate spacer may include a plurality of layers. For example, the gate spacer may sequentially include an insulation liner, an insulation spacer, an insulation protective layer, and the like.

In the integrated circuit 200, the first gate pattern GP1 and the first nano-sheet NS1 of a first vertical level Lv_F1 may delineate the first pull-up transistor PU1 and the second pull-up transistor PU2. Also, the second gate pattern GP2 and the second nano-sheet NS2 of a second vertical level Lv_F2 may delineate the first pull-down transistor PD1 and the second pull-down transistor PD2. Also, the second gate pattern GP2 and the second nano-sheet NS2 of a second vertical level Lv_F2 may delineate the first pass gate transistor PG1 and the second pass gate transistor PG2.

In the integrated circuit 200, the first node ND1 and the second node ND2 are at the first vertical level Lv_F1 and the second vertical level Lv_F2. The first node ND1 may correspond to a wire connecting gates of the second pull-up transistor PU2 and the second pull-down transistor PD2 to the source/drain region of the first pass gate transistor PG1. Also, the first node ND1 may correspond to a wire connecting gates of the second pull-up transistor PU2 and the second pull-down transistor PD2 to a source/drain region between the first pull-up transistor PU1 and the first pull-down transistor PD1. Similarly, the second node ND2 may correspond to a wire connecting gates of the first pull-up transistor PU1 and the first pull-down transistor PD1 to the source/drain region of the second pass gate transistor PG2. Also, the second node ND2 may correspond to a wire connecting the gates of the first pull-up transistor PU1 and the first pull-down transistor PD1 to a source/drain region between the second pull-up transistor PU2 and the second pull-down transistor PD2.

A plurality of contacts CA1, CA2, and CA3 may be referred to as first and second node contacts, word line contacts, and bit line contacts according to positions thereof. First node contacts may connect source/drain regions of the first pull-down transistor PD1 and the second pull-down transistor PD2 to the first node ND1. Second node contacts may connect source/drain regions of the first pull-up transistor PU1 and the second pull-up transistor PU2 to the second node ND2. Word line contacts may connect gates of the first pass gate transistor PG1 and the second pass gate transistor PG2 to the word line WL. Bit line contacts may connect the source/drain region of the first pass gate transistor PG1 to the bit line BL and connect the source/drain region of the second pass gate transistor PG2 to the bit line bar BLB.

The plurality of first wiring lines ML1 may be included in the front-side power delivery network FSPDN of a third vertical level Lv_F3. The plurality of first wiring lines ML1 may be electrically connected to the plurality of contacts CA1, CA2, and CA3 described above. The plurality of first wiring lines ML1 may delineate the first node ND1 and the second node ND2, the word line WL, the bit line BL, and the bit line bar BLB. In some implementations, the plurality of first wiring lines ML1 may include aluminum (Al), tungsten (W), titanium (Ti), tantalum (Ta), palladium (Pd), platinum (Pt), molybdenum (Mo), a metal silicide, or a combinations thereof.

The plurality of second wiring lines ML2 may be included in the back-side power delivery network BSPDN of a fourth vertical level Lv_B1. The plurality of second wiring lines ML2 may delineate power patterns that supply power to the power rail PR. The plurality of second wiring lines ML2 may include a second wiring line ML2 electrically connected to the first power rail PR1 and a second wiring line ML2 electrically connected to the second power rail PR2. In some implementations, the plurality of second wiring lines ML2 may include aluminum (Al), tungsten (W), titanium (Ti), tantalum (Ta), palladium (Pd), platinum (Pt), molybdenum (Mo), a metal silicide, or a combinations thereof.

In the integrated circuit 200, the first to fourth unit cells UC1, UC2, UC3, and UC4 may be arranged in a mirror-image symmetrical structure. A first unit cell UC1 and a second unit cell UC2 may be arranged to form a mirror-image symmetrical structure in the second direction D2, and the first unit cell UC1 and a fourth unit cell UC4 may be arranged to form a mirror-image symmetrical structure in the first direction D1. Also, a third unit cell UC3 and the fourth unit cell UC4 may be arranged to form a mirror-image symmetrical structure in the second direction D2, and the second unit cell UC2 and the third unit cell UC3 may be arranged to form a mirror-image symmetrical structure in the first direction D1.

In detail, around the power rail PR, the first gate patterns GP1 delincating the first pull-up transistor PU1 and the second pull-up transistor PU2 may be arranged to form a mirror-image symmetrical structure, the second gate patterns GP2 delineating the first pull-down transistor PD1 and the second pull-down transistor PD2 may be arranged to form a mirror-image symmetrical structure, and the second gate patterns GP2 delineating the first pass gate transistor PG1 and the second pass gate transistor PG2 may be arranged to form a mirror-image symmetrical structure. Here, the plurality of first gate patterns GP1 and the plurality of second gate patterns GP2 arranged to form a mirror-image symmetrical structure may be arranged in parallel to each other.

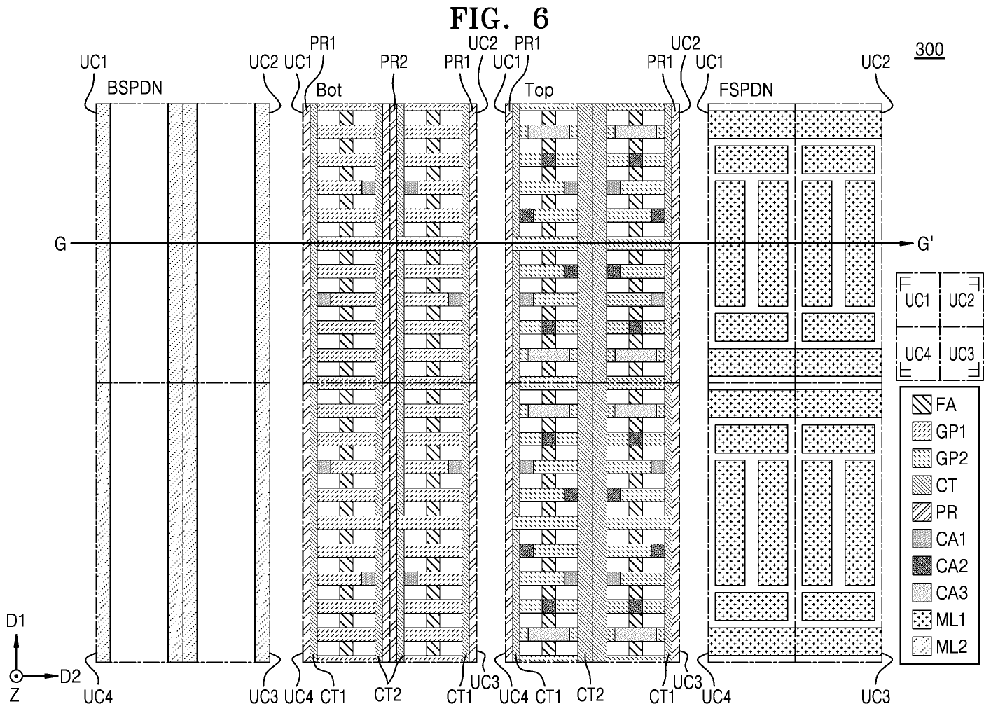

FIGS. 6 to 10 are diagrams showing examples of integrated circuits. Most of components delineating integrated circuits 300, 400, and 500 described below and materials delincating the components are substantially the same as or similar to those described above with reference to FIGS. 4 and 5A to 5F. Therefore, for convenience of explanation, descriptions below will focus on differences from the integrated circuit 100 described above.

Here, although the back-side power delivery network BSPDN, the bottom transistor layer Bot, the top transistor layer Top, and the front-side power delivery network FSPDN are stacked in a vertical direction Z as described above with reference to FIG. 2, they are shown on one plane for convenience of explanation.

FIG. 6 depicts an example of a planar layout showing an integrated circuit 300, and FIG. 7 depicts a cross-sectional view taken along a line G-G′ of FIG. 6. Referring to FIGS. 6 and 7 together, in the integrated circuit 300, a planar layout of a stacked structure including 4 unit cells UC1, UC2, UC3, and UC4 corresponding to 1-bit in a 2×2 arrangement is shown, wherein a rectangular portion indicated by dashed-dotted lines may correspond to a 1-bit unit cell, such as UC of FIG. 3.

In the integrated circuit 300, the gate cut line CT extends in the first direction D1 while cutting both the plurality of first gate patterns GP1, and there is a plurality of second gate patterns GP2 with the fin-type active pattern FA therebetween. Therefore, the plurality of first gate patterns GP1 and the plurality of second gate patterns GP2 may have substantially the same width in the second direction D2.

In the integrated circuit 300, a gate cut line CT extending between the first unit cell UC1 and the second unit cell UC2 from among gate cut lines CT may have a lower structure CT_L and an upper structure CT_U having different shapes. The power rail PR is disposed at the center of the lower structure CT_L, and gate cut lines CT may be arranged on both sidewalls of the power rail PR. Unlike this, the power rail PR is not disposed in the upper structure CT_U, and the gate cut line CT may include an insulation material layer only.

In the integrated circuit 300, the first power rail PR1 and the second power rail PR2 may have different shapes. The first power rail PR1 may have a shape extending from the semiconductor substrate 101 (refer to FIG. 11) to the second vertical level Lv_F2 beyond the first vertical level Lv_F1. Unlike this, the second power rail PR2 may have a shape extending from the semiconductor substrate 101 to the first vertical level Lv_F1.

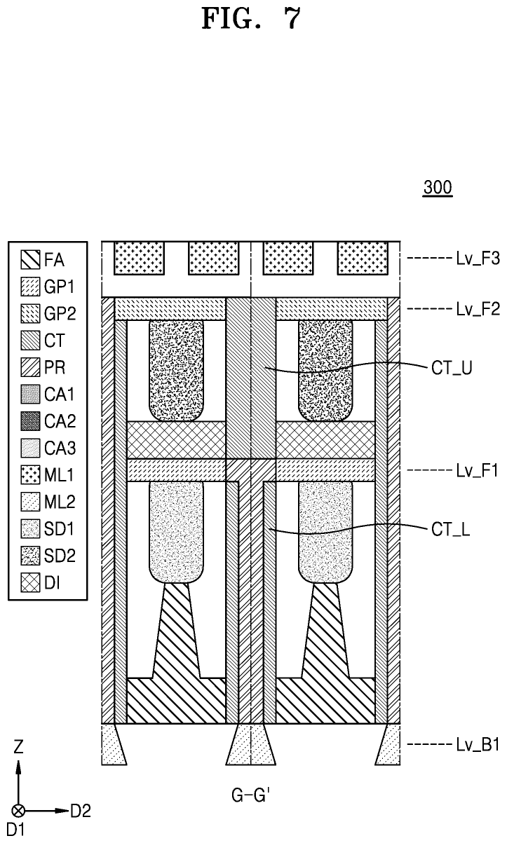

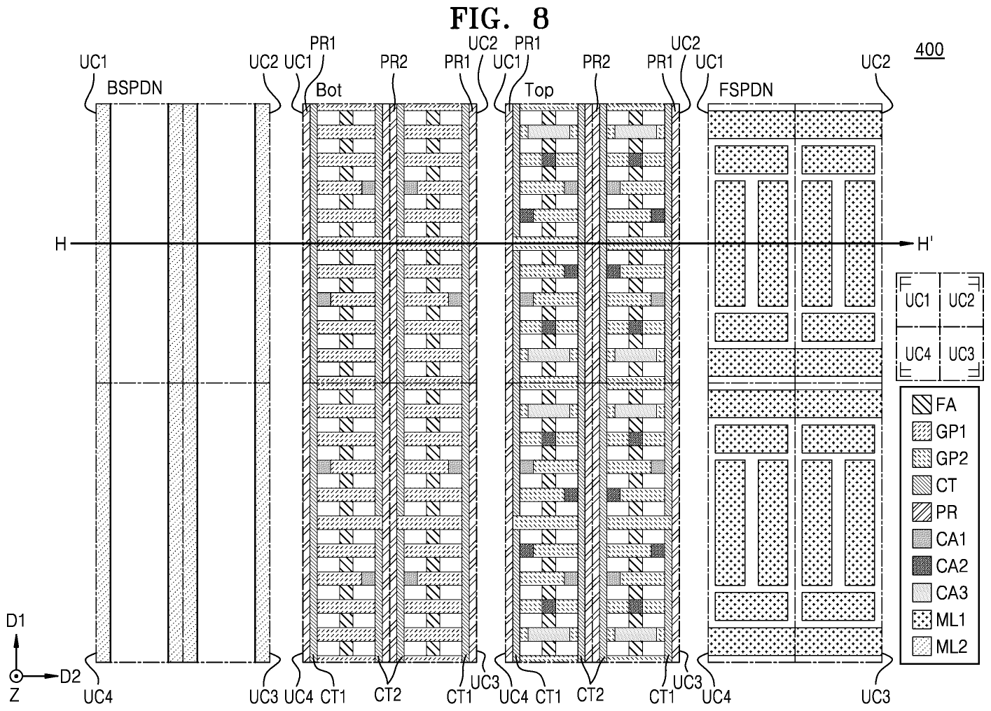

FIG. 8 depicts an example of a planar layout showing an integrated circuit 400, and FIG. 9 depicts a cross-sectional view taken along a line H-H′ of FIG. 8. Referring to FIGS. 8 and 9 together, in the integrated circuit 400, a planar layout of a stacked structure including 4 unit cells UC1, UC2, UC3, and UC4 corresponding to 1-bit in a 2×2 arrangement is shown, wherein a rectangular portion indicated by dashed-dotted lines may correspond to a 1-bit unit cell, such as UC from FIG. 3.

In the integrated circuit 400, the gate cut line CT extending in the first direction D1 while cutting both the plurality of first gate patterns GP1 and the plurality of second gate patterns GP2 with the fin-type active pattern FA therebetween may be disposed. Therefore, the plurality of first gate patterns GP1 and the plurality of second gate patterns GP2 may have substantially the same width in the second direction D2.

In the integrated circuit 400, a gate cut line CT extending between the first unit cell UC1 and the second unit cell UC2 from among gate cut lines CT has a lower structure CT_L and an upper structure CT_U having different shapes. In the lower structure CT_L, the gate cut lines CT is arranged only on both sidewalls of the power rail PR, and the gate cut line CT is not disposed on the bottom surface of the power rail PR. The second wiring line ML2 directly contacts the bottom surface of the power rail PR located in the lower structure CT_L. In the upper structure CT_U, the gate cut lines CT are arranged on both sidewalls of the power rail PR, and the gate cut line CT may also be disposed on the bottom surface of the power rail PR.

In the integrated circuit 400, the first power rail PR1 and the second power rail PR2 may have different shapes. The first power rail PR1 may have a shape extending from the semiconductor substrate 101 (refer to FIG. 11) to the second vertical level Lv_F2 beyond the first vertical level Lv_F1. The second power rail PR2 may have a separated shape that extends from the semiconductor substrate 101 to the first vertical level Lv_F1, is spaced apart from the first vertical level Lv_F1 in the vertical direction Z by a certain distance, and extends from the first vertical level Lv_F1 to the second vertical level Lv_F2.

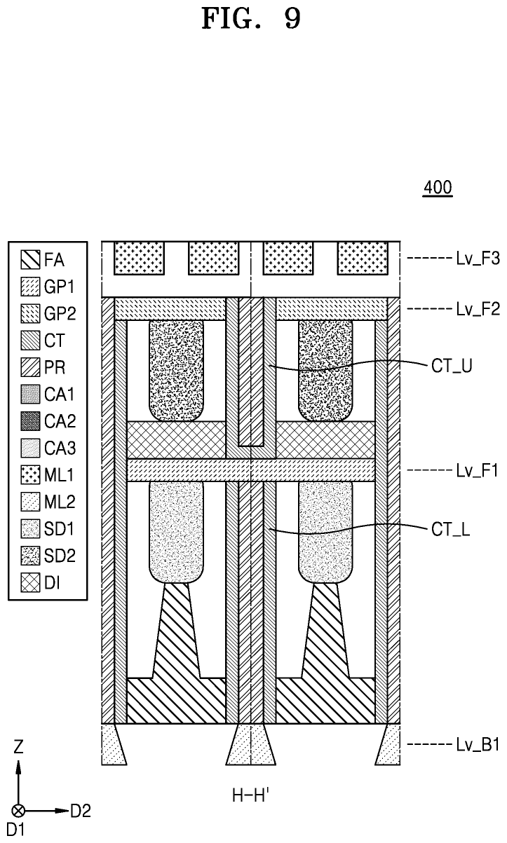

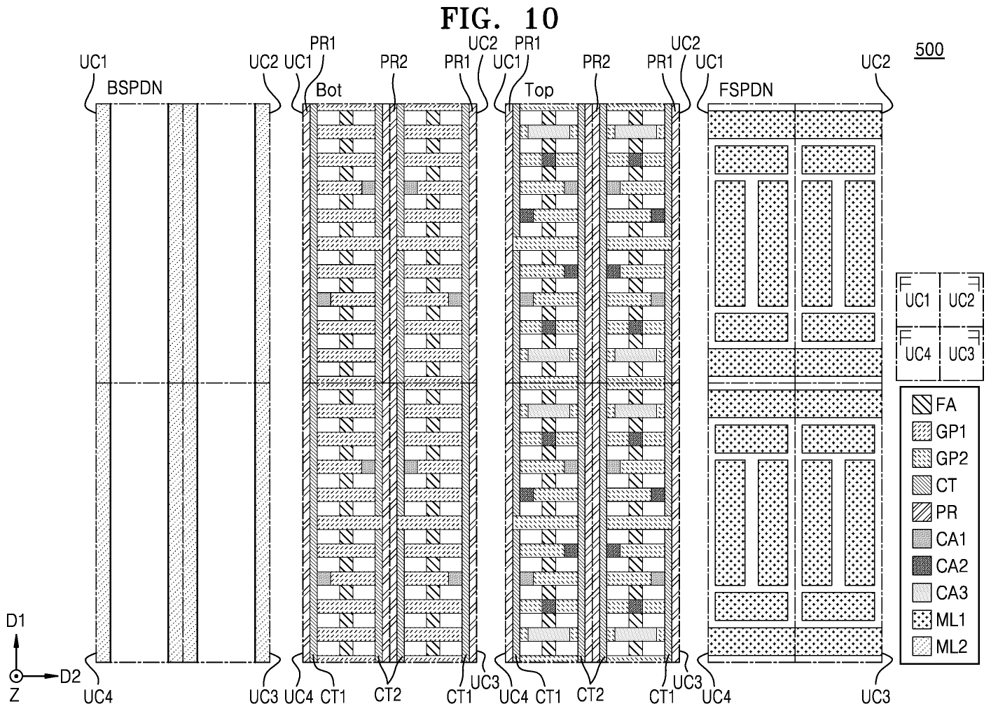

FIG. 10 depicts an example of a planar layout showing an integrated circuit 500. Referring to FIG. 10, in the integrated circuit 500, a planar layout of a stacked structure including 4 unit cells UC1, UC2, UC3, and UC4 corresponding to 1-bit in a 2×2 arrangement is shown, where a rectangular portion indicated by dashed-dotted lines may correspond to a 1-bit unit cell, such as UC of FIG. 3.

In the integrated circuit 500, the first unit cell UC1 and the second unit cell UC2 may be arranged to form a mirror-image symmetrical structure in the second direction D2, and the third unit cell UC3 and the fourth unit cell UC4 may be arranged to form a mirror-image symmetrical structure in the second direction D2. However, the first unit cell UC1 and the fourth unit cell UC4 may delineate a repeating pattern structure in the first direction D1, and the second unit cell UC2 and the third unit cell UC3 may delineate a repeating pattern structure in the first direction D1.

In detail, around the power rail PR, the first gate patterns GP1 delincating the first pull-up transistor PU1 and the second pull-up transistor PU2 may be arranged to form a mirror-image symmetrical structure, the second gate patterns GP2 delineating the first pull-down transistor PD1 and the second pull-down transistor PD2 may be arranged to form a mirror-image symmetrical structure, and the second gate patterns GP2 delineating the first pass gate transistor PG1 and the second pass gate transistor PG2 may be arranged to form a mirror-image symmetrical structure. Here, the plurality of first gate patterns GP1 and the plurality of second gate patterns GP2 arranged to form a mirror-image symmetrical structure may be arranged in parallel to each other.

FIGS. 11 to 22 are cross-sectional views showing an example of a method of manufacturing an integrated circuit. For convenience of explanation, descriptions will be given below with reference to a cross-sectional view taken along a line C-C′ of FIG. 4. Here, particular operations may be performed in an order different from that described below. For example, two successively described operations may be performed substantially and simultaneously or may be performed in an order opposite to the order described below.

Referring to FIG. 11, after a plurality of sacrificial layers and a plurality of nano-sheet layers are alternately stacked one-by-one on a semiconductor substrate 101, portions of the plurality of sacrificial layers, the plurality of nano-sheet layers, and the semiconductor substrate 101 are etched, thereby forming a device isolation trench in the semiconductor substrate 101. Therefore, a plurality of fin-type active patterns FA protruding in the vertical direction Z from the semiconductor substrate 101 are formed, and the plurality of nano-sheets may remain on fin top surfaces of the plurality of fin-type active patterns FA in a shape extending long in the first direction D1. Next, a plurality of first source/drain regions SD1 may be formed on both sides of a nano-sheet by etching portions of the fin-type active pattern FA on both sides of the nano-sheet. Also, a first interlayer insulation layer ILD1 may be formed around the plurality of fin-type active patterns FA and the first source/drain region SD1.

Referring to FIG. 12, a first gate space GR1 is formed by etching upper portions of the plurality of fin-type active patterns FA and the first source/drain region SD1. The first gate space GR1 may be provided as a space in which the plurality of first gate patterns GP1 (refer to FIG. 13) are formed in a subsequent process. Therefore, the upper portion of the first source/drain region SD1 may be partially removed.

Referring to FIG. 13, the plurality of first gate patterns GP1 filling the first gate space GR1 and extending in the second direction D2 are formed. After a conductive layer filling the first gate space GR1 is formed, the conductive layer may be etched back, such that the conductive layer exists only in the first gate space GR1. Therefore, the plurality of first gate patterns GP1 may be formed in the first gate space GR1. Here, a vertical level at which the plurality of first gate patterns GP1 are formed may be referred to as the first vertical level Lv_F1.

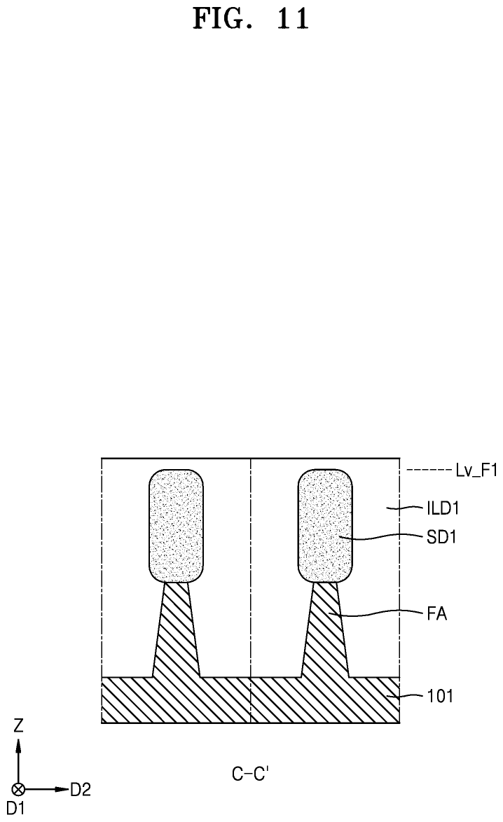

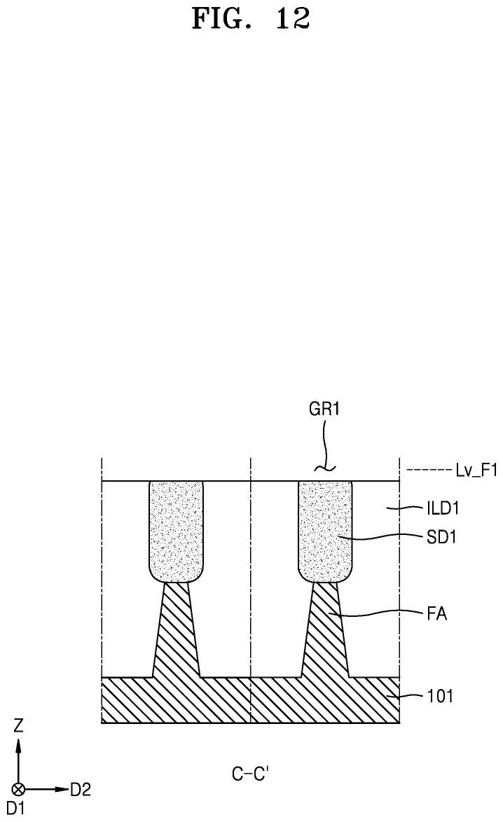

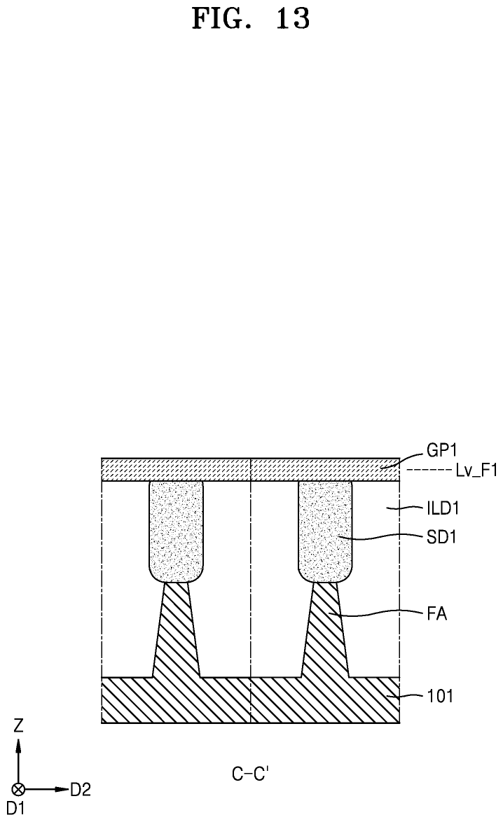

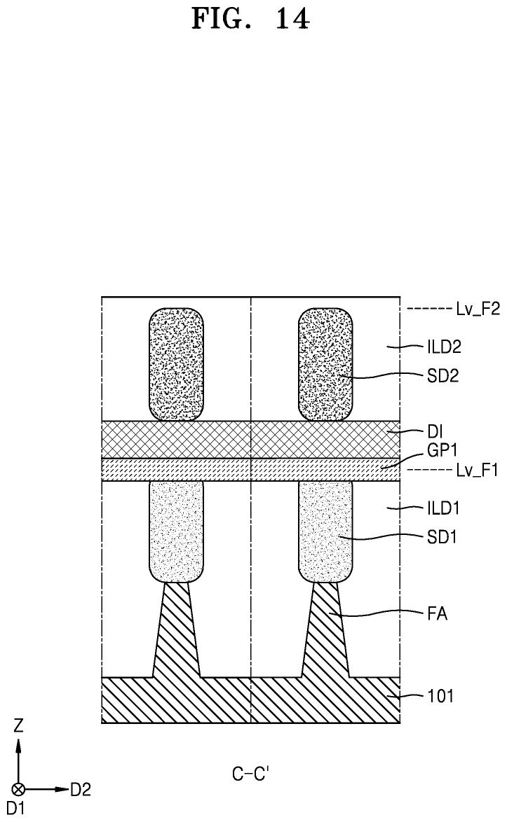

Referring to FIG. 14, an isolating insulation layer D1 is formed on the plurality of first gate patterns GP1, and a plurality of nano-sheets are further formed on the fin top surfaces of the plurality of fin-type active patterns FA. The plurality of second source/drain regions SD2 may be formed on both sides of a nano-sheet by etching portions of the fin-type active pattern FA on both sides of the nano-sheet. Also, a second interlayer insulation layer ILD2 may be formed around the plurality of fin-type active patterns FA and the second source/drain region SD2.

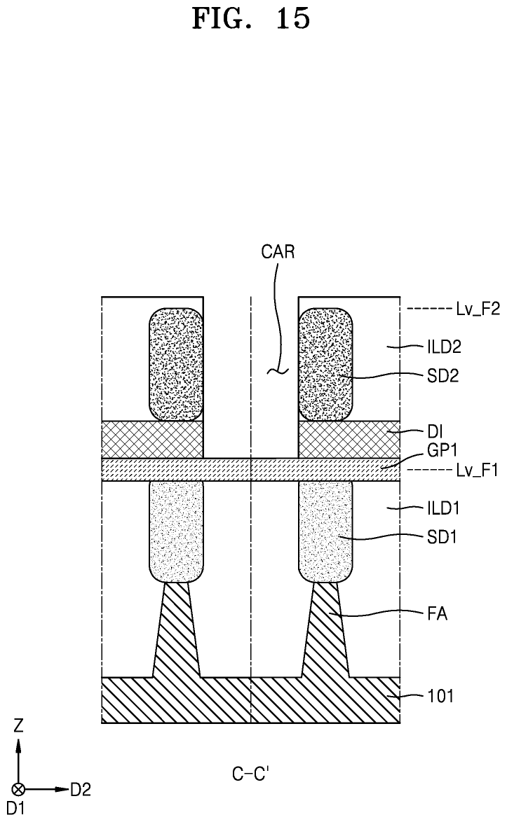

Referring to FIG. 15, a contact space CAR penetrating through the second interlayer insulation layer ILD2 and the isolating insulation layer D1 is formed. Portions of top surfaces of the plurality of first gate patterns GP1 may be exposed by the contact space CAR.

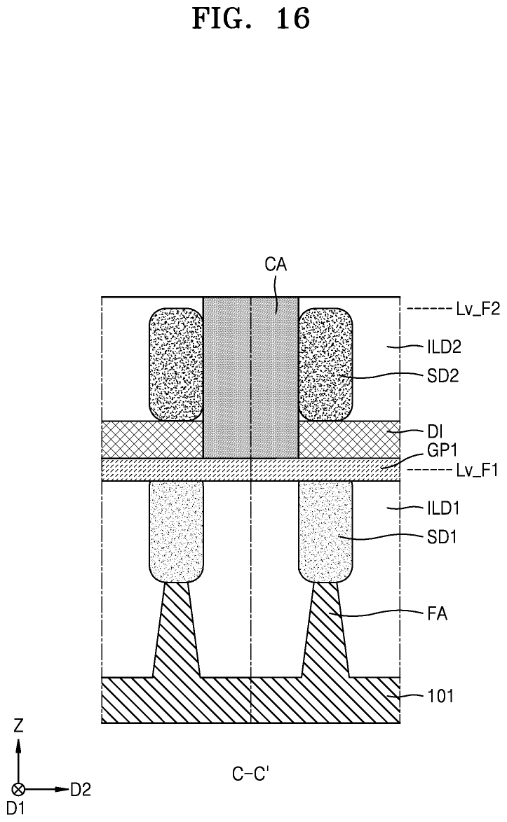

Referring to FIG. 16, a contact CA that fills the contact space CAR and extends long in the vertical direction Z is formed. After forming a conductive layer filling the contact space CAR, the conductive layer may be etched back, such that the conductive layer exists only in the contact space CAR. Therefore, the contact CA may be formed in the contact space CAR.

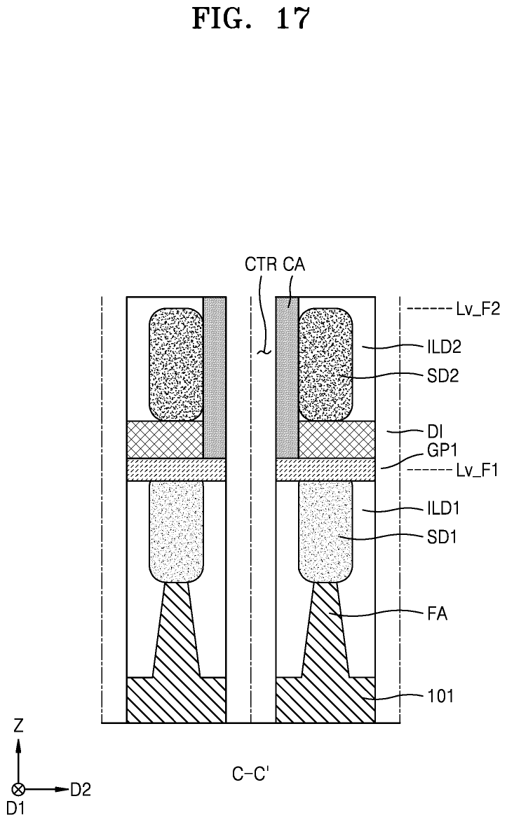

Referring to FIG. 17, a gate cut space CTR penetrating through the contact CA, the second interlayer insulation layer ILD2, and the first interlayer insulation layer ILD1 is formed. The plurality of first gate patterns GP1 may be cut by the gate cut space CTR and side surfaces thereof may be exposed.

Referring to FIG. 18, the gate cut line CT that fills the gate cut space CTR and extends long in the vertical direction Z is formed. An insulation layer may be formed only on inner walls of the gate cut space CTR. Therefore, the gate cut line CT may be formed, such that the gate cut space CTR has the hollow central portion.

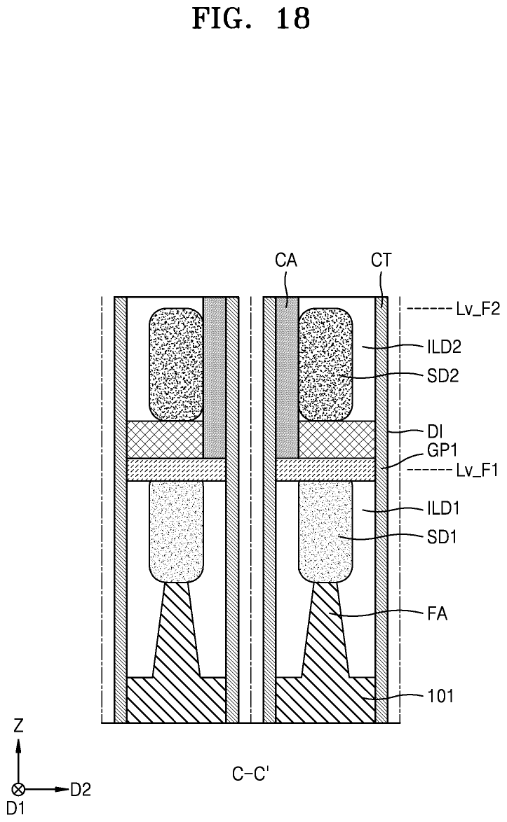

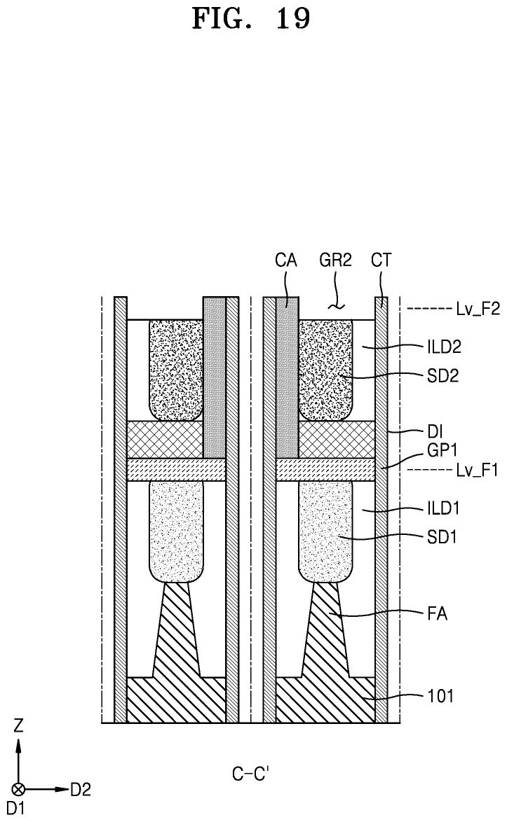

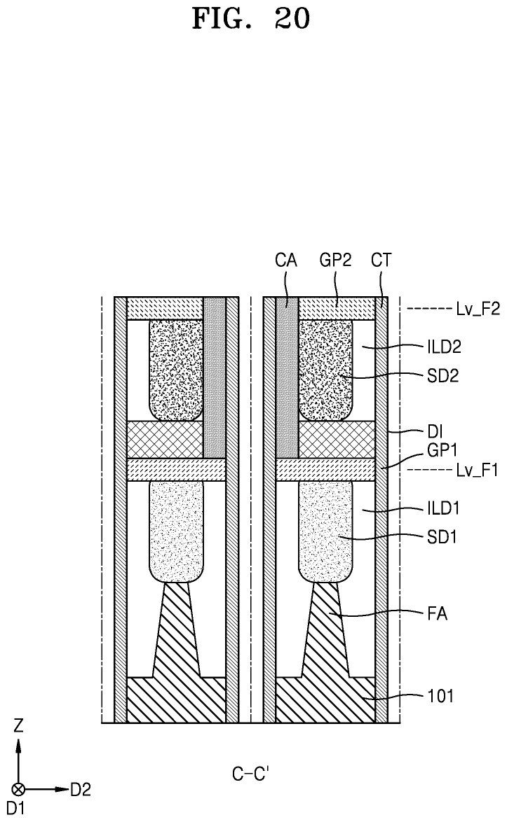

Referring to FIG. 19, a second gate space GR2 is formed by etching upper portions of the plurality of fin-type active patterns FA and the second source/drain region SD2. The second gate space GR2 may be provided as a space in which the plurality of second gate patterns GP2 (refer to FIG. 20) are formed in a subsequent process. Therefore, the upper portion of the second source/drain region SD2 may be partially removed.

Referring to FIG. 20, the plurality of second gate patterns GP2 filling the second gate space GR2 are formed. After a conductive layer filling the second gate space GR2 is formed, the conductive layer may be etched back, such that the conductive layer exists only in the second gate space GR2. Therefore, the plurality of second gate patterns GP2 may be formed in the second gate space GR2. Here, a vertical level at which the plurality of second gate patterns GP2 are formed may be referred to as the second vertical level Lv_F2.

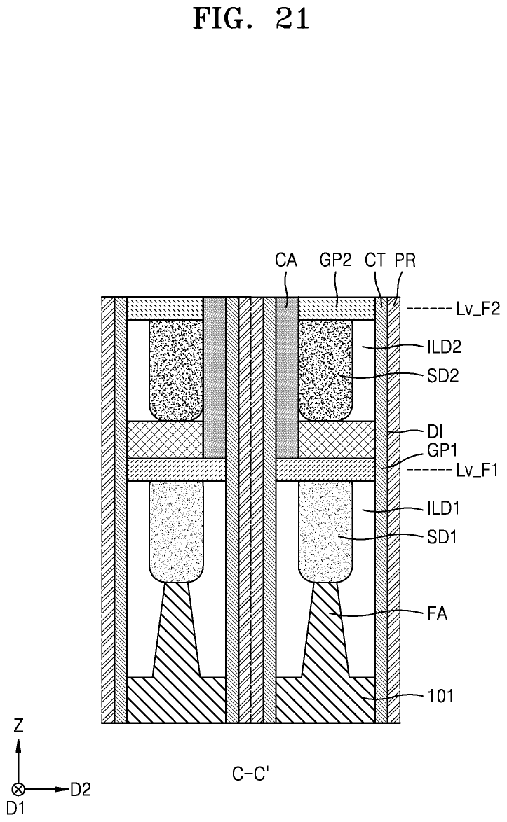

Referring to FIG. 21, the power rail PR that fills the central portion of the gate cut space CTR and extends long in the vertical direction Z is formed. After a conductive layer filling the central portion of the gate cut space CTR is formed, the conductive layer may be etched back, such that the conductive layer exists only in the central portion of the gate cut space CTR. Therefore, the power rail PR may be formed at the central portion of the gate cut space CTR. In this example, a vertical level of an uppermost end of the second power rail PR is substantially identical to the second vertical level Lv_F2.

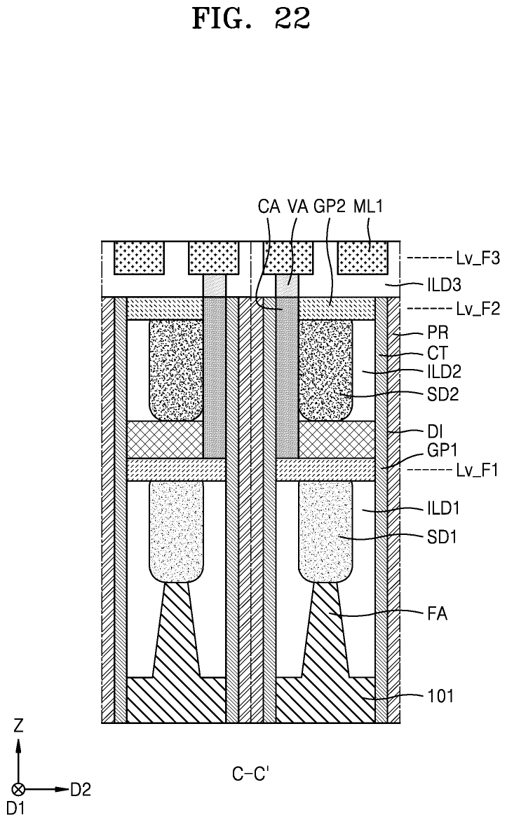

Referring to FIG. 22, the front-side power delivery network FSPDN including a third interlayer insulation layer ILD3 and the plurality of first wiring lines ML1 is formed on the plurality of second gate patterns GP2. Vertical vias VA may be formed to electrically connect the plurality of first wiring lines ML1 to the contact CA. Here, a vertical level at which the plurality of first wiring lines ML1 are formed may be referred to as the third vertical level Lv_F3.

Referring back to FIG. 5C, the back-side power delivery network BSPDN including the plurality of second wiring lines ML2 is formed below the power rail PR. Vertical vias may be further formed to electrically connect the plurality of second wiring lines ML2 to the power rail PR. Here, a vertical level at which the plurality of second wiring lines ML2 are formed may be referred to as the fourth vertical level Lv_B1.

When the integrated circuit 100 is manufactured according to the above-stated method, based on the layout of a 3DS structure in which the wiring connection structure of transistors delincating an SRAM device may be simplified while minimizing the planar area occupied by the unit cells UC (refer to FIG. 3), the integrated circuit 100 with a minimized size and improved reliability may be implemented.

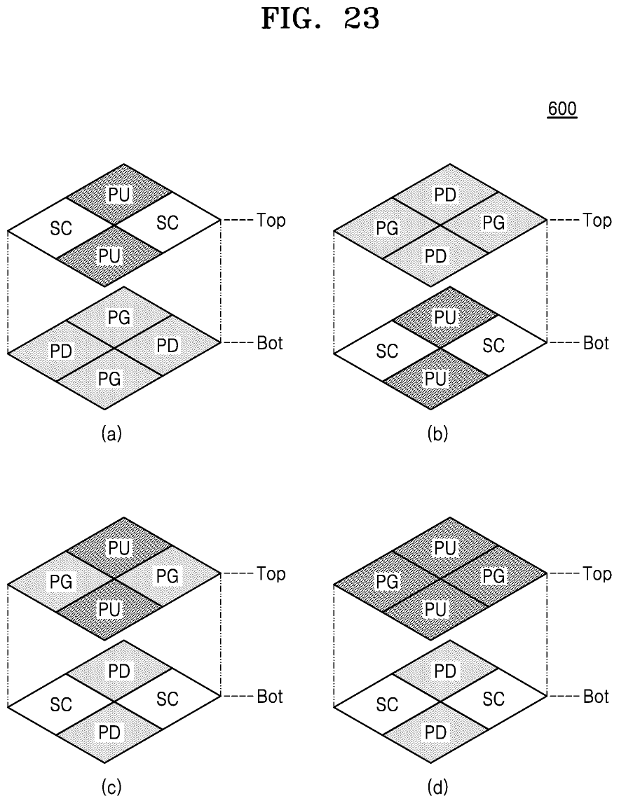

FIG. 23 depicts an example of a conceptual diagram showing the arrangement of transistors in an integrated circuit. Referring to FIG. 23, an integrated circuit 600 including a FET having a 3DS structure according to the present embodiment may be an SRAM device including 6 transistors as shown in the circuit diagram.

The integrated circuit 600 may include, for example, 2 pass gate transistors PG, 2 pull-up transistors PU, 2 pull-down transistors PD, and 2 shared contacts SC. The arrangement of 6 transistors in the integrated circuit 600 may vary as described below.

As shown in (a) of FIG. 23, the 2 pull-down transistors PD and the 2 pass gate transistors PG may be included in the bottom transistor layer Bot, and the pull-down transistors PD and the pass gate transistors PG may be formed as nMOS-FETs. The 2 pull-up transistors PU and 2 nodes ND may be included in the top transistor layer Top, and the pull-up transistors PU may be formed as pMOS-FETs.

As shown in (b) of FIG. 23, the 2 pull-up transistors PU and the 2 nodes ND may be included in the bottom transistor layer Bot, and the pull-up transistors PU may be formed as pMOS-FETs. The 2 pull-down transistors PD and the 2 pass gate transistors PG may be included in the top transistor layer Top, and the pull-down transistors PD and the pass gate transistors PG may be formed as nMOS-FETs.

As shown in (c) of FIG. 23, the 2 pull-down transistors PD and the 2 nodes ND may be included in the bottom transistor layer Bot, and the pull-down transistors PD may be formed as nMOS-FETs. The 2 pull-up transistors PU and the 2 pass gate transistors PG may be included in the top transistor layer Top, wherein the pull-up transistors PU may be formed as pMOS-FETs, and the pass gate transistors PG may be formed as nMOS-FETs.

As shown in (d) of FIG. 23, the 2 pull-down transistors PD and the 2 nodes ND may be included in the bottom transistor layer Bot, and the pull-down transistors PD may be formed as nMOS-FETs. The 2 pull-up transistors PU and the 2 pass gate transistors PG may be included in the top transistor layer Top, wherein the pull-up transistors PU and the pass gate transistors PG may be formed as pMOS-FETs.

However, arrangements of transistors other than those depicted in FIG. 23 are possible.

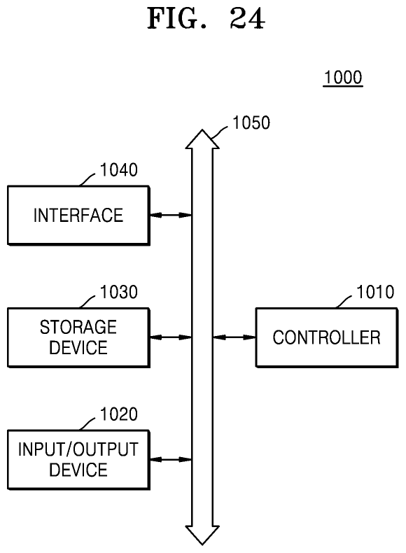

FIG. 24 depicts an example of a configuration diagram showing a system 1000 including an integrated circuit. Referring to FIG. 24, the system 1000 includes a controller 1010, an input/output device 1020, a storage device 1030, an interface 1040, and a bus 1050.

System 1000 may be a mobile system or a system that transmits or receives information. In some implementations, the mobile system may be a portable computer, a web tablet, a mobile phone, a digital music player, or a memory card.

The controller 1010 is for controlling a program executed on the system 1000 and may include a microprocessor, a digital signal processor, a microcontroller, or the like.

The input/output device 1020 may be used to input or output data to or from system 1000. The system 1000 may be connected to an external device, e.g., a personal computer or a network, and exchange data with the external device by using the input/output device 1020. The input/output device 1020 may be, for example, a touch screen, a touch pad, a keyboard, or a display device.

The storage device 1030 may store data for operation of the controller 1010 or data processed by the controller 1010. The storage device 1030 may include any one of integrated circuits 100, 200, 300, 400, 500, and 600 according to the inventive concept described above.

The interface 1040 may be a data transmission path between the system 1000 and an external device. The controller 1010, the input/output device 1020, the storage device 1030, and the interface 1040 may communicate with one another via the bus 1050.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the inventive concept has been particularly shown and described with reference to examples thereof, it will be understood that various changes in form and details may be made therein without departing from the spirit and scope of the following claims.

What is claimed is:

1. An integrated circuit comprising:
a fin-type active pattern on a substrate, the fin-type active pattern extending in a first direction and protruding in a vertical direction;
a plurality of first gate patterns at a first vertical level above the substrate, the plurality of first gate patterns being spaced apart from one another in the first direction, and crossing the fin-type active pattern in a second direction perpendicular to the first direction;
a plurality of second gate patterns at a second vertical level higher than the first vertical level, the plurality of second gate patterns being spaced apart from one another in the first direction and crossing the fin-type active pattern in the second direction;
a first gate cut line and a second gate cut line cutting both of the plurality of first gate patterns and the plurality of second gate patterns with the fin-type active pattern therebetween, and extending in the first direction, wherein the first and second gate cut lines each have a first side facing the other first side of the first and second gate cut lines;
a first power rail disposed on a second side of the first gate cut line and extending in the first direction, wherein the second side of the first gate cut line is opposite the first side of the first gate cut line; and
a second power rail disposed on a second side of the second gate cut line and extending in the first direction wherein the second side of the second gate cut line is opposite the first side of the second gate cut line,
wherein, from among the plurality of first gate patterns, a first gate pattern defining a positive supply voltage terminal penetrates through the second gate cut line and contacts a sidewall of the second power rail, and,
from among the plurality of second gate patterns, a second gate pattern defining a negative supply voltage terminal penetrates through the first gate cut line and contacts a sidewall of the first power rail.

2. The integrated circuit of claim 1, wherein the first power rail and the second power rail extend in the vertical direction from the substrate to the second vertical level, and
the first gate pattern defining the positive supply voltage terminal and the second gate pattern defining the negative supply voltage terminal overlap each other in the vertical direction.

3. The integrated circuit of claim 2, wherein the first gate pattern defining the positive supply voltage terminal is located between first gate patterns defining at least a portion of a first pull-up transistor and a second pull-up transistor.

4. The integrated circuit of claim 3, wherein the second gate pattern defining the negative supply voltage terminal is located between second gate patterns defining at least a portion of a first pull-down transistor and a second pull-down transistor.

5. The integrated circuit of claim 4, wherein the second gate pattern defining at least a portion of the first pull-down transistor and the second pull-down transistor are located between second gate patterns defining at least a portion of a first pass gate transistor and a second pass gate transistor.

6. The integrated circuit of claim 4, wherein the first gate patterns defining at least a portion of the first pull-up transistor overlap the second gate patterns defining at least a portion of the first pull-down transistor in the vertical direction, and the second pull-up transistor overlaps the second pull-down transistor in the vertical direction.

7. The integrated circuit of claim 1, wherein first gate patterns defining at least a portion of a first node overlap second gate patterns defining at least a portion of the first node in the vertical direction, and first gate patterns defining at least a portion of a second node overlap second gate patterns defining at least a portion of the second node in the vertical direction.

8. The integrated circuit of claim 7, wherein a first gate pattern defining at least a portion of the first node and a second gate pattern defining at least a portion of the first node are electrically connected to each other through a first contact, and
a first gate pattern defining at least a portion of the second node and a second gate pattern defining at least a portion of the second node are electrically connected to each other through a second contact.

9. The integrated circuit of claim 8, wherein a front-side power delivery network comprising a plurality of first wiring lines is disposed at a third vertical level higher than the second vertical level, and
a first wiring line electrically connected to the first node and a first wiring line electrically connected to the second node from among the plurality of first wiring lines are arranged to face each other.

10. The integrated circuit of claim 9, wherein a back-side power delivery network comprising a plurality of second wiring lines is disposed at a fourth vertical level below the substrate, and
a second wiring line electrically connected to the first power rail and a second wiring line electrically connected to the second power rail from among the plurality of second wiring lines are arranged to face each other.

11. An integrated circuit comprising:
a first fin-type active pattern and a second fin-type active pattern on a substrate, the first fin-type active pattern and the second fin-type active pattern extending in a first direction, spaced apart from each other in a second direction perpendicular to the first direction, and protruding in a vertical direction;
a plurality of first gate patterns at a first vertical level above the substrate, the plurality of first gate patterns being spaced apart from one another in the first direction, and crossing first fin-type active pattern and the second fin-type active pattern in the second direction;
a plurality of second gate patterns at a second vertical level higher than the first vertical level, the plurality of second gate patterns being spaced apart from one another in the first direction, and crossing the first fin-type active pattern and the second fin-type active pattern in the second direction;
two first gate cut lines cutting both of the plurality of first gate patterns and the plurality of second gate patterns with the first fin-type active pattern and the second fin-type active pattern therebetween, and extending in the first direction;
one second gate cut line disposed between the first fin-type active pattern and the second fin-type active pattern, cutting both of the plurality of first gate patterns and the plurality of second gate patterns, and extending in the first direction;
first power rails arranged inside the first gate cut lines and extending in the first direction; and
a second power rail disposed inside the second gate cut line and extending in the first direction,
wherein, from among the plurality of first gate patterns, first gate patterns defining a positive supply voltage terminal penetrate through the second gate cut line and contact sidewalls of the second power rail, and,
from among the plurality of second gate patterns, second gate patterns defining a negative supply voltage terminal penetrate through the first gate cut lines and contact sidewalls of the first power rails.

12. The integrated circuit of claim 11, wherein a vertical level of an uppermost end of each of the first power rails is substantially identical to the second vertical level, and
a vertical level of an uppermost end of the second power rail is substantially identical to the first vertical level.

13. The integrated circuit of claim 11, wherein the plurality of first gate patterns are arranged to form a mirror-image symmetrical structure around the second power rail,
the first gate patterns defining the positive supply voltage terminal contact both sidewalls of the second power rail, and
the plurality of second gate patterns are arranged to form a mirror-image symmetrical structure around the second power rail, and
the second gate patterns defining the negative supply voltage terminal contact sidewalls of different first power rails.

14. The integrated circuit of claim 11, wherein the first gate pattern defining the positive supply voltage terminal is located between first gate patterns defining at least a portion of a first pull-up transistor and a second pull-up transistor,
the second gate pattern defining the negative supply voltage terminal is located between second gate patterns defining at least a portion of a first pull-down transistor and a second pull-down transistor, and
the second gate patterns defining at least a portion of the first pull-down transistor and the second pull-down transistor are located between second gate patterns defining at least a portion of a first pass gate transistor and a second pass gate transistor.

15. The integrated circuit of claim 11, wherein, around the second power rail,
first gate patterns defining at least a portion of a first pull-up transistor and a second pull-up transistor are arranged to form a mirror-image symmetrical structure,
second gate patterns defining at least a portion of a first pull-down transistor and a second pull-down transistor are arranged to form a mirror-image symmetrical structure, and
second gate patterns defining at least a portion of a first pass gate transistor and a second pass gate transistor are arranged to form a mirror-image symmetrical structure.

16. The integrated circuit of claim 15, wherein a plurality of first gate patterns and a plurality of second gate patterns arranged to form a mirror-image symmetrical structure are arranged in parallel to each other.

17. The integrated circuit of claim 11, wherein first gate patterns defining at least a portion of a first node and a second node from among the plurality of first gate patterns and second gate patterns defining at least a portion of the first node and the second node from among the plurality of second gate patterns overlap each other in the vertical direction,
a first gate pattern defining at least a portion of the first node and a second gate pattern defining at least a portion of the first node are electrically connected to each other through a first contact, and
a first gate pattern defining at least a portion of the second node and a second gate pattern defining at least a portion of the second node are electrically connected to each other through a second contact.

18. The integrated circuit of claim 17, wherein the first gate patterns defining at least a portion of the first node and the second node and the second gate patterns defining at least a portion of the first node and the second node are arranged in parallel to each other.

19. An integrated circuit to implement an SRAM device comprising six transistors in a 3-dimensional stack structure, the integrated circuit comprising:
a fin-type active pattern on a substrate, the fin-type active pattern extending in a first direction and protruding in a vertical direction;
a plurality of first gate patterns at a first vertical level above the substrate, the plurality of first gate patterns being spaced apart from one another in the first direction, and crossing the fin-type active pattern in a second direction perpendicular to the first direction;
a plurality of second gate patterns at a second vertical level higher than the first vertical level, the plurality of second gate patterns being spaced apart from one another in the first direction, and crossing the fin-type active pattern in the second direction;
a first gate cut line and a second gate cut line cutting both of the plurality of first gate patterns and the plurality of second gate patterns with the fin-type active pattern therebetween, and extending in the first direction, wherein the first and second gate cut lines each have a first side facing the other first side of the first and second gate cut lines;
a first power rail disposed on a second side of the first gate cut line and extending in the first direction, wherein the second side of the first gate cut line is opposite the first side of the first gate cut line; and
a second power rail disposed on a second side of the second gate cut line and extending in the first direction, wherein the second side of the second gate cut line is opposite the first side of the second gate cut line,
wherein, from among the plurality of first gate patterns, a first gate pattern defining a positive supply voltage terminal is disposed to penetrate through the second gate cut line and contact a sidewall of the second power rail,
from among the plurality of second gate patterns, a second gate pattern defining a negative supply voltage terminal is disposed to penetrate through the first gate cut line and contact a sidewall of the first power rail,
first gate patterns defining at least a portion of a first pull-up transistor and a second pull-up transistor from among the plurality of first gate patterns are located with the first gate pattern defining the positive supply voltage terminal therebetween,
second gate patterns defining at least a portion of a first pull-down transistor and a second pull-down transistor from among the plurality of second gate patterns are located with the second gate pattern defining the negative supply voltage terminal therebetween, and
second gate patterns defining at least a portion of a first pass gate transistor and a second pass gate transistor from among the plurality of second gate patterns are located with the second gate patterns defining at least a portion of the first pull-down transistor and the second pull-down transistor therebetween.

20. The integrated circuit of claim 19, wherein first gate patterns defining at least a portion of a first node and a second node from among the plurality of first gate patterns and second gate patterns defining at least a portion of the first node and the second node from among the plurality of second gate patterns overlap each other in the vertical direction, a first gate pattern defining at least a portion of the first node and a second gate pattern defining at least a portion of the first node are electrically connected to each other through a first contact, and a first gate pattern defining at least a portion of the second node and a second gate pattern defining at least a portion of the second node are electrically connected to each other through a second contact,
a front-side power delivery network comprising a plurality of first wiring lines is disposed at a third vertical level higher than the second vertical level, and, from among the plurality of first wiring lines, a first wiring line electrically connected to the first node and a first wiring line electrically connected to the second node are arranged to face each other, and
a back-side power delivery network comprising a plurality of second wiring lines is disposed at a fourth vertical level below the substrate, and, from among the plurality of second wiring lines, a second wiring line electrically connected to the first power rail and a second wiring line electrically connected to the second power rail are arranged to face each other.
